(19) United States
(12) Patent Application Publication
(10) Pub. No.: US 2013/0175076 A1
(43) Pub. Date: Jul. 11, 2013

(54) Component Carrier, Electric Conductor and Method for Producing a Component Carrier as Well as an Electric Conductor

(71) Applicant: E.G.O. Elektro-Geratebau GmbH, Oberderdingen (DE)

(72) Inventor: Axel Hiller, Kraichtal (DE)

(73) Assignee: E.G.O. Elektro-Geratebau GmbH, Oberderdingen (DE)

(21) Appl. No.: 13/739,454

(22) Filed: Jan. 11, 2013

(30) Foreign Application Priority Data
Jan. 11, 2012 (DE) DE102012200343.6

(51) Int. Cl. H05K 1/11; H05K 3/34

(52) U.S. Cl. CPC H05K 1/11; H05K 3/34
USPC 174/261; 29/832; 29/840

(57) ABSTRACT

The disclosure relates to a component carrier or printed circuit board for electronic components. According to embodiments, a component carrier may include a first contact face for a contact to a first component, a second contact face for a contact to a second component as well as a conductor track that electrically couples the first and the second contact face. The conductor track may include a conductor recess along the conductor track extending through the printed circuit board. An electric conductor may be arranged in the conductor recess extending over the entire course thereof and electrically coupled to the conductor track.

### CROSS REFERENCE TO RELATED APPLICATIONS

This application claims the benefit of German patent application DE 10 2012 200 343.6, filed on Jan. 11, 2012, the contents of which are incorporated by reference for all that it teaches.

### TECHNICAL FIELD

The disclosure relates to a component carrier, in particular a printed circuit board, for electronic and/or electric components. Furthermore, the disclosure relates to an electric conductor of such a component carrier as well as to a method for producing a corresponding component carrier.

### BACKGROUND

Component carriers, electric conductors or methods for producing the same are well-known to the persons skilled in the art and are constantly used throughout the entire field of electrical engineering or the like. The electrical conductivity of an electric conductor of a component carrier is improved the bigger the cross-section of the electric conductor would get. The ability to conducting comparatively high currents is particularly envisioned in power electronics, although the total space allocated to a component carrier may be limited.

### SUMMARY

The disclosure herein provides a component carrier and an electric conductor, as well as a method of the above-mentioned type, by means of which a significantly improved electrical conductivity and heat conductivity is achieved compared to existing technologies. The wording of the claims is incorporated into the content of the description by explicit reference. Some of the features and characteristics listed below in a non-exhaustive way apply to the component carrier, to the electric conductor as well as to the method. Sometimes they are only described once but are valid independent from one another and in any combination for the component carrier as well as for the electric conductor and the method. Furthermore, the order of the listed features is not binding but can rather be modified or combined corresponding to an optimized component carrier, an optimized electric conductor or an optimized method.

The electric conductors mentioned herein are to be dimensioned in a way as to ensure that an acceptable compromise is reached between the total required space of a component carrier and the conduction cross-section of the electric conductor. According to one aspect of the disclosure, a component carrier may include two opposing sides and two contact faces, each face configured for electrical coupling to a component. A conductor track may be positioned on a first side of the component carrier and electrically couple the two contact faces. A conductor recess may extend from one side toward the other side of the component carrier along the conductor track. The conductor recess may be configured for electrical coupling to an electric conductor arranged in the recess and extending over an entire length of the recess. The component carrier may be configured in a planar configuration.

According to another aspect, an electric conductor may include a conductor track and a conductor. The conductor track may be arranged on a first or second side of a component carrier. The conductor may be arranged substantially parallel to the conductor track in a conductor recess extending from the first or second side in a direction toward the other side.

According to yet another aspect, a method for providing electrical conductivity for a component carrier may include providing a conductor track positioned on a first or second side of the component carrier that includes a first and second contact face. A conductor recess is provided in the component carrier in a region of the conductor track substantially along the conductor track extending from one side toward the other side. A conductor may be positioned in the conductor recess.

These and further features arise not only from the claims but also from the description and the drawings wherein the individual features can be realized on their own or together with other features in the type of sub-combinations of an embodiment of the disclosure and in other fields and can represent advantageous embodiments capable or being protected on their own for which hereby protection is claimed. The division of the application into individual sections and cross headings does not limit the general validity of the contents thereof.

### BRIEF DESCRIPTION OF THE DRAWINGS

Different embodiments of the disclosure are schematically shown in the drawings and will subsequently be explained in more detail. The embodiments shown in the individual figures partially provide features the other embodiments of the disclosure shown do not provide. However, the features can be combined with one another without extending the scope of the present disclosure. The figures show in:

FIG. 1a conductor track arranged on a component carrier according to embodiments of the disclosure,

FIG. 2a conductor track arranged on a component carrier according to embodiments of the disclosure,

FIG. 3a conductor track arranged on a component carrier according to embodiments of the disclosure,

FIG. 4 a sectional view of a component carrier according to embodiments of the disclosure according to line I-I in FIG. 1,

FIG. 5 a sectional view of a component carrier according to embodiments of the disclosure according to line II-II in FIG. 1,

FIG. 6a sectional view of a component carrier according to embodiments of the disclosure according to line in FIG. 2,

FIG. 7a sectional view of a component carrier according to embodiments of the disclosure according to line IV-IV in FIG. 3, as well as

FIG. 8 a sectional view of a component carrier according to the disclosure according to FIG. 7, however in another embodiment.

### DETAILED DESCRIPTION

According to the disclosure, a component carrier, in particular a printed circuit board, is intended for electronic and/or electric components, which may be configured in a planar or flat manner and which may include a first side as well as a second side opposing the first side. Here, the component carrier may include a first contact face for a contact to a first, particularly electronic component as well as a second contact face for a contact to a second, particularly electronic component. Furthermore, the component carrier may include a conductor track which connects the first contact face to the second contact face in an electrically-conductive way and which is arranged on the first side of the component carrier. The component carrier may include a conductor recess which, starting from the first side or the second side, extends in the direction to the respective other side wherein said conductor recess runs along the conductor track. An electric conductor may be arranged in the conductor recess substantially extending over the entire course thereof, which conductor is connected to the conductor track in an electrically-conductive way. Here, the conductor recess does not only extend through the conductor track but may also extend at least partially through the electrically-non-conductive carrier material, for example a resin board which is usually used for printed circuit boards.

By arranging the electric conductor along the conductor track, not only is the track material which is no longer present due to the recess replaced, but additional conductor material is provided for the electrical connection of the first contact face to the second contact face. So, altogether the conductor cross-section is significantly increased at least between the contact faces. In doing so, however, the original periphery of the component carrier is essentially maintained, at least however merely slightly increased since the increase of the conductor cross-section is effected essentially in the interior of the component carrier or reaches into the depth thereof.

An electric conductor according to the disclosure can, for example, be a wire, a sheet metal strip or the like. However, also an electrically-conductive plastic, paint or the like can be used in some embodiments of the disclosure if reasonable in the scope of the disclosure.

The conductor recess preferably extends as far to the first and second contact face that the electric conductor to be used or to be arranged is part of the current path in the entire region of the current path between the first contact face and the second contact face. Otherwise, the conductor track would, for example, be the weakest link of the current track.

In one embodiment of the disclosure, the conductor recess completely extends from the first side to the second side, i.e. completely through the component carrier. Correspondingly, the electric conductor is preferably selected or configured in such a way that the entire available space in the conductor recess is filled up by this electric conductor. It is obvious that the bigger the additional electric conductor in the conductor recess is, the higher are the currents that can be used. Preferably, the conductor track is wider than the conductor recess. In particular, the conductor track may be 1.5 to 5 times wider than the conductor recess.

In a further embodiment of the disclosure, the conductor recess runs centrally along the conductor track and particularly interrupts or divides the latter there. That way an equal distribution of the conductor track and the conductor recess is achieved. The conductor track can be used as a cursor, for example for a milling device or the like. The equal distribution or the central interruption or division of the conductor track also proves to be advantageous in the use of solder mask, and also in the metalization of so-called released surfaces in the region of the recess.

In a further embodiment of the disclosure, a side wall, particularly both side walls, of the conductor recess are provided with an electrically-conductive layer as part of the conductor, preferably they are metalized, in particular with the same material as the conductor track. This material can preferably, but not exclusively, be copper. This configuration increases the electrical conductivity and the heat conductivity of the conductor track, protects the edges or side walls of the conductor recess and stabilizes the component carrier. Moreover, this way the contact area between the conductor track and the electric conductor to be arranged in the conductor recess is increased which is also advantageous for the conducting current between the two contact faces.

In a further embodiment of the disclosure, the conductor track has a greater width in the region of the contact face than in the region between the contact faces along the conductor recesses. This way, a big or a comparatively bigger bearing face for tin-solder or its equivalent is provided in the contacting of electric components to the contact faces. Furthermore, an increase in the conductor cross-section in the region of the contact faces is achieved by means of the tin-solder or its equivalent, wherein said increase then preferably extends as far as into the region of the conductor recesses.

In a further embodiment of the disclosure, the conductor track provides a contact recess which surrounds the contact face preferably in a cup-like manner and/or completely or only partially in a ring-shaped manner in the region of a contact face and which preferably changes over into the conductor track recess. The contact recess starts form the free surface of the contact face and extends into the component carrier. By means of the contact recess, additional space is created in order to accommodate an electric conductor according to the above description.

In an embodiment of the disclosure, the conductor recess and/or the contact recess is/are filled with tin-solder. In this configuration, the electric conductor may be produced in and/or at the conductor recess during a work step that is required anyway, particularly preferred during soldering, for example by means of a soldering bath, wave soldering or the like.

In an embodiment of the disclosure, the conductor, a contact recess, the conductor track, the contact faces as well as tin-solder applied form an electric conductor, preferably with a nearly continuous, preferably constant conductor cross-section. In a further embodiment of the disclosure, an electrically-conductive component is arranged along the conductor recess, preferably a wire, a metal bridge or the like which is connected to the conductor track in an electrically-conducting way, preferably by means of tin-solder or the equivalent, namely along the course of the conductor recess. This way, depending on the material used for the additional electric conductor, the electric conductivity and the heat conductivity of the entire conductor is further increased in the region between the contact faces.

In a further embodiment of the disclosure, several conductor recesses are provided along a conductor, such as two or three, in particular parallel to one another and/or configured in the same way. This way a further increase of the available conductor cross-section is achieved.

In an embodiment of the disclosure, the ratio between the width of the conductor track and the width of the conductor recess lies between 1:0.9 and 1:0.1, in particular between 1:0.7 and 1:0.3. In a further embodiment of the disclosure, the width B of the conductor recess is smaller than the thickness D of the component carrier and the width B is more than twice the thickness D of conductor track. An ideal ratio can be found by combining fluid properties, for example of the tin-solder, a required stability of the component carrier as well as a conductor cross-section to be achieved.

An electric conductor may also be provided herein, where the electric conductor may include a conductor track arranged on the first and/or the second side of the component carrier as well as a conductor arranged in a conductor recess. Starting from one of the sides, said conductor recess extends in the direction to the other side and runs essentially parallel to the conductor track.

Furthermore, a method for producing an above-described component carrier is described herein, where the component carrier comprises a conductor track arranged on a first side and/or a second side of the component carrier and where the component carrier comprises a first and a second contact face. In one operation of the method, a conductor recess is applied/introduced in the component carrier in the region of the conductor track essentially along the conductor track, where the conductor recess, starting from one side, extends in the direction to the other side. This can be effected in case of an already existing or previously applied conductor track, that is to say separating the latter. As an alternative, it can be effected before the conductor track is applied or even before copper-plating the conductor track.

In another subsequent operation, a conductor is arranged in the conductor recess, if applicable together with the conductor track during metalization. In a further operation, if applicable, an electrically-conductive connection is realized between the conductor track and the conductor if it has not been produced before.

In an alternative development of the method, tin-solder or one of its equivalents is filled in the conductor recess for producing the electrically-conductive connection, where the conductor recess is completely filled with tin-solder. In this case, the steps comprising the arrangement of the conductor and the connection to the conductor track fall together.

In a further development of the method, the side walls of the conductor recess are coated in an electrically-conductive way, preferably with the same material the conductor track is made of, in particular with copper. This can be effected beforehand or afterwards.

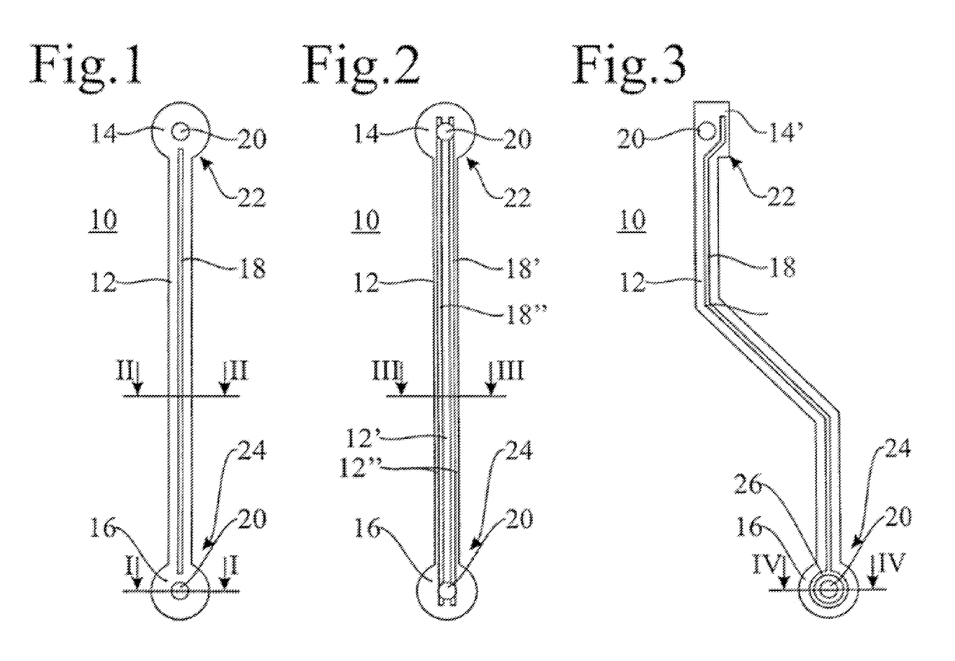

Turning now to the figures, in FIG. 1, a planar component carrier 10 according to the disclosure is shown, e.g. an integrated circuit board, which completely surrounds a conductor track 12 laterally with a first contact face 14 and a second contact face 16 or which serves as a carrier for the latter. According to FIG. 1, the conductor track 12 is provided along its course with a central conductor recess 18 which, as will be explained by the FIGS. 5, 6 and 7 later on, is filled at least partially with an electric conductor. The first contact face 14 and the second contact face 16 comprise in each case a round recess 20 for taking up contact pins, tabs or the like of particularly electrical components. Generally, the conductor track 12 consists of copper, or as an alternative of any other metal or electrically-conductive material that can be used for the use in a printed circuit board. The pins or tabs of the electrical components not shown in FIG. 1 are soldered to the first contact face 14 or the second contact face 16, for example in a soldering bath, according to known methods.

In contrast to FIG. 1, in FIG. 2 two conductor recesses 18′, 18″ are provided. As the conductor recess 18 of FIG. 1, these conductor recesses 18′, 18″ run essentially parallel and along as well as within the conductor track 12. The conductor track 12 is divided by the conductor recesses 18′, 18″ into a conductor path 12′ as well as two conductor path outer sections 12″ flanking the conductor path 12′. In each case, the conductor recesses 18′, 18″ extend up into the region 22 of the first contact face 14 and the region 24 of the second contact face 16, and therein in each case beyond the recesses 20. In an advantageous configuration, the conductor recesses 18′, 18″ do not extend completely through the component carrier 10 in the regions 22, 24 so that the path remains connected to the rest of the component carrier 10. In contrast to FIG. 2, the conductor recess 18 of FIG. 1 ends shortly before the recess 20. Both embodiments are to be awarded advantages. So, according to FIG. 1, a significantly easier generation of the recess 18 is possible which furthermore provides a high stability for the component carrier 10, in particular also in the region of the recesses 20. By means of the continuation of the recesses 18′, 18″ of FIG. 2 as far as into the region of the recesses 20, or beyond the recesses 20, a very good electrical contacting of the electric conductor (which is not shown) which is arranged in the respective recess 18 to the contact pins or contact tabs of the electrical components (also not shown) is generated. Under certain circumstances, generally all the conductors including the conductor recess can be slightly bent off in order to lie straight against the contact pins.

In contrast to the conductor tracks of FIG. 1 and FIG. 2, the conductor track 12 of FIG. 3 is configured double-bended in its course. This configuration shall serve as an example for any course of the conductor tracks 12 on the component carrier 10 which might also be significantly longer and/or branched. Furthermore, the first contact face 14′ of FIG. 3 differs from the first contact face 14 of FIG. 1 and FIG. 2 by its non-circular contour. There, also the conductor recess 18 is configured in such a way that it passes by the recess 20 of the first contact face 14′. The second contact face 16 comprises a contact recess 26 which directly changes over into the conductor recess 18. The contact recess 26 surrounds the recess 20 in a ring-shaped manner, however it does not penetrate the component carrier 10 completely.

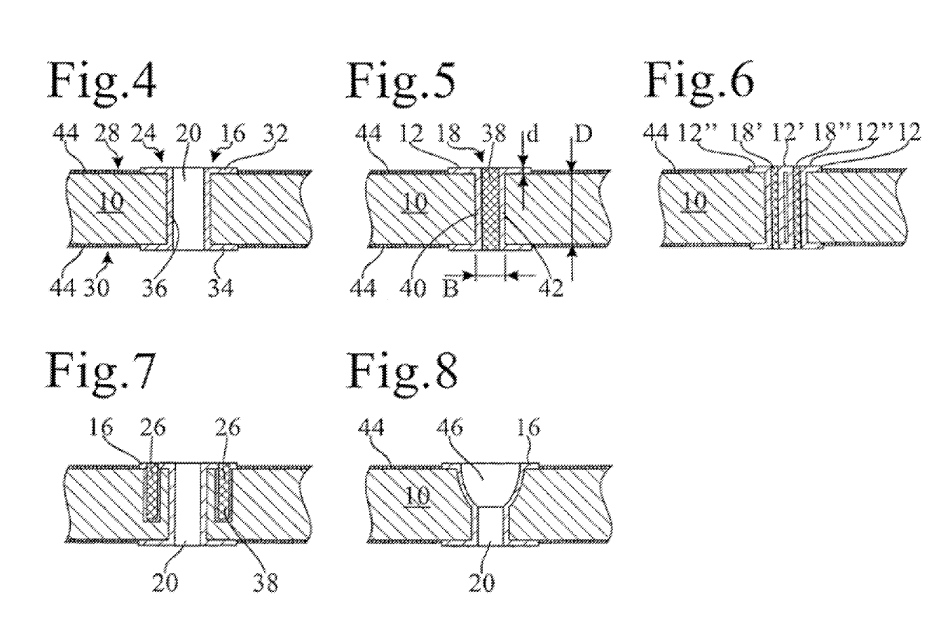

In FIG. 4, a sectional view of the component carrier 10 in the region 24 of the second contact face 16 is shown according to line I-I of FIG. 1. The recess 20 penetrates the component carrier from the first side 28 thereof up to the second side 30 thereof. The first contact face 16 consists of a part 32 which is arranged on the first side 28, a second part 34 which is arranged on the side 30 as well as a third part 36 which penetrates the component carrier 10 or which is arranged at an inner wall. These parts are configured in a way that is well-known to the persons skilled in the art and can be produced, for example, by etching the surface as well as by metalizing, for example after producing the recess 20.

In FIG. 5, a sectional view of the conductor track 12 of FIG. 1 is shown according to line II-II. The conductor track 12 is provided with a conductor recess 18 in which an electric conductor 38 is arranged. Here, this electric conductor 38 is tin-solder, for example, which is supplied to the component carrier 10 by solder bathing which is usually conducted anyway. It can be seen from FIG. 5. that the side wall 40 of the conductor recess 18 is provided with an electrically-conductive layer 42 which essentially corresponds to the material used for the conductor track 12. It is obvious that the conductor cross-section of the conductor track 12 is significantly increased through the presence of the electric conductor 38.

It proved to be advantageous to select the width B of the conductor recess 18 smaller than the thickness D of the component carrier 10. Furthermore, in an advantageous configuration, the width B should be more than twice the width d of the conductor track 12.

In order to prevent undesirable spreading of the tin-solder on the surface of the component carrier 10 beyond the region of the conductor track 12, the component carrier 10 is provided with a so-called solder stop paint 44 or the like in these essentially un-used regions.

In FIG. 6, an embodiment of the conductor track 12 of FIG. 5 is shown, where the illustration of FIG. 6 corresponds to the section line of FIG. 2. It can be seen that the conductor track 12 comprises two conductor recesses 18′, 18″ whose basic structure corresponds to the one of the conductor track 12 of FIG. 5. These conductor recesses 18′, 18″ divide the conductor track 12 into a conductor path 12′ and two conductor track outer sections 12″ which flank the conductor path 12′. It can be seen that a connection between the conductor path 12′ and at least one of the conductor track outer regions 12″ after producing the conductor recesses 18′, 18″ should persist, similar as with reference to FIG. 2 or as subsequently described with reference to FIG. 7.

FIG. 7 shows the second contact face 16 corresponding to section line IV-IV of FIG. 3. The contact face 16 is provided with a contact recess 26 which surrounds the recess 20 in a ring-shaped manner and which penetrates the printed circuit board at least partially by approximately 75%. According to the conductor recesses 18, 18′ and 18″, the contact recess 26 is provided with an electric conductor 38. Together with the conductor track 12 and the contact faces 14, 16, the electric conductor 38 forms, as the previously mentioned electric conductors, a joint current path having a minimum cross-section. This way, higher currents can be transported/conducted than would be the case without the conductor recess or the contact recess 26 with the conductor 38 therein.

FIG. 8 shows another embodiment of the second contact face of FIG. 7. This one comprises a cup-like recess 46 which changes over into the recess 20. It can be seen, that after soldering of a component which is not shown or the contact pins and/or tabs thereof, more tin-solder or its equivalent will be present in the region 46 than in the region 20. This way the available electric conductor cross-section is increased as well.

1. A component carrier for electronic and electric components, comprising:
a first side and a second side opposing said first side;
a first contact face configured for a contact to a first component and a second contact face configured for a contact to a second component;
a conductor track electrically coupling said first contact face to said second contact face and positioned on said first side of said component carrier; and
a conductor recess which extends, starting from said first side or said second side, in a direction to said other side along said conductor track, and configured for electrical coupling to an electric conductor arranged in said conductor recess extending substantially over an entire length of the conductor recess,
wherein said component carrier is configured in a planar configuration.

2. The component carrier of claim 1, wherein said conductor recess completely extends through said component carrier starting from said first side to said second side.

3. The component carrier of claim 1, wherein said conductor track is 1.5 to 5 times wider than said conductor recess.

4. The component carrier of claim 1, wherein said conductor recess runs centrally along said conductor track.

5. The component carrier of claim 4, wherein said conductor recess divides said conductor track centrally.

6. The component carrier of claim 1, wherein a side wall of said conductor recess is provided with an electrically-conductive layer as a part of said conductor.

7. The component carrier of claim 6, wherein both said side walls of said conductor recess are provided with said electrically-conductive layer as a part of said conductor.

8. The component carrier of claim 7, wherein both said side walls of said conductor recess are provided with said electrically-conductive layer as a part of said conductor being the same material as said conductor track.

9. The component carrier of claim 1, wherein said conductor track has a greater width in a region of said contact faces than in a region between said contact faces along said conductor recess.

10. The component carrier of claim 1, wherein said conductor track comprises a contact recess surrounding said contact face in a region of said contact face, said contact recess changing over into said conductor recess.

11. The component carrier of claim 10, wherein said conductor recess is filled with tin-solder, wherein said conductor, a contact recess, said conductor track, said contact faces as well as applied tin-solder jointly form an electric conductor having a conductor cross-section.

12. The component carrier of claim 10, wherein said contact recess is filled with tin-solder, wherein said conductor, a contact recess, said conductor track, said contact faces as well as applied tin-solder jointly form an electric conductor having a conductor cross-section.

13. The component carrier of claim 1, wherein an electrically-conductive component is arranged along said conductor recess, being electrically connected to said conductor track.

14. The component carrier of claim 1, wherein said electrical connection to said conductor track in an electrically-conductive way is by means of tin-solder along a course of said conductor recess.

15. The component carrier of claim 1, wherein several conductor recesses are provided along a conductor.

16. The component carrier of claim 15, wherein said several conductor recesses are parallel to one another.

17. The component carrier of claim 15, wherein said several conductor recesses are configured identically.

18. The component carrier of claim 1, wherein a ratio between a width of said conductor track and a width B of said conductor recess is between 1:0.9 and 1:0.1.

19. The component carrier of claim 18, wherein said width B of said conductor recess is smaller than a thickness D of said component carrier.

20. The component carrier of claim 18, wherein said width B of said conductor recess is more than twice a thickness D of said conductor track.

21. An electric conductor comprising:
a conductor track arranged on a first side or on a second side of a component carrier; and
a conductor arranged in a conductor recessextending from said first side or said second side in a direction to said other side and substantially parallel to said conductor track.

22. A method for providing electrical conductivity for a component carrier, the method comprising:
providing a conductor track positioned on a first side or on a second side of said component carrier comprising a first and a second contact face;
providing a conductor recess in said component carrier in a region of said conductor track substantially along said conductor trackand extending from one side in a direction to said other side; and
positioning a conductor in said conductor recess.

23. The method of claim 22, further comprising electrically coupling said conductor track and said conductor.

24. The method of claim 22, further comprising filling said conductor recess with tin-solder for producing an electrically-conductive connection.

25. The method of 24, wherein said conductor recess is completely filled with tin-solder.

26. The method of claim 22, further comprising coating side walls of said conductor recess with an electrically-conductive material.

27. The method of claim 26, wherein said side walls of said conductor recess are coated with the same material associated with said conductor track.
